(19) United States
(12) Patent Application Publication
(10) Pub. No.: US 2025/0112045 A1
(43) Pub. Date: Apr. 3, 2025

(54) DRY DEVELOPMENT OF RESISTS

(71) Applicant: Lam Research Corporation, Fremont, CA (US)

(72) Inventors: Boris Volosskiy, San Jose, CA (US); Timothy William Weidman, Sunnyvale, CA (US); Samantha SiamHwa Tan, Newark, CA (US); Chenghao Wu, San Jose, CA (US); Kevin Li Gu, Mountain View, CA (US)

(73) Assignee: Lam Research Corporation, Fremont, CA (US)

(21) Appl. No.: 18/980,854

(22) Filed: Dec. 13, 2024

Related U.S. Application Data
(63) Continuation of application No. 17/309,587, filed on Jun. 8, 2021, now Pat. No. 12,211,691.
(60) Provisional application No. 62/782,578, filed on Dec. 20, 2018.

(51) Int. Cl. H01L 21/027; G03F 7/16; G03F 7/36; H01L 21/308

(52) U.S. Cl. CPC H01L 21/0274; G03F 7/162; G03F 7/167; G03F 7/36; H01L 21/308

(57) ABSTRACT

Dry development of resists can be useful, for example, to form a patterning mask in the context of high-resolution patterning. Dry development may be advantageously accomplished by a method of processing a semiconductor substrate including providing in a process chamber a photopatterned resist on a substrate layer on a semiconductor substrate, and dry developing the photopatterned resist by removing either an exposed portion or an unexposed portion of the resist by a dry development process comprising exposure to a chemical compound to form a resist mask. The resist may be an EUV-sensitive organo-metal oxide or organo-metal-containing thin film EUV resist.

### INCORPORATION BY REFERENCE

An Application Data Sheet is filed concurrently with this specification as part of the present application. Each application that the present application claims benefit of or priority to as identified in the concurrently filed Application Data Sheet is incorporated by reference herein in their entireties and for all purposes.

### BACKGROUND

Patterning of thin films in semiconductor processing is often an important step in the fabrication of semiconductors. Patterning involves lithography. In conventional photolithography, such as 193 nm photolithography, patterns are printed by emitting photons from a photon source onto a mask and printing the pattern onto a photosensitive photoresist, thereby causing a chemical reaction in the photoresist that, after development, removes certain portions of the photoresist to form the pattern.

Advanced technology nodes (as defined by the International Technology Roadmap for Semiconductors) include nodes 22 nm, 16 nm, and beyond. In the 16 nm node, for example, the width of a typical via or line in a Damascene structure is typically no greater than about 30 nm. Scaling of features on advanced semiconductor integrated circuits (ICs) and other devices is driving lithography to improve resolution.

### SUMMARY

Dry development of resists can be useful, for example, to form a patterning mask in the context of high-resolution patterning. According to some aspects of this disclosure, dry development may be advantageously accomplished by a method of processing a semiconductor substrate including providing in a process chamber a photopatterned resist on a substrate layer on a semiconductor substrate, and dry developing the photopatterned resist by removing either an exposed portion or an unexposed portion of the resist by a dry development process comprising exposure to a chemical compound to form a resist mask. In some embodiments, the resist may be an EUV-sensitive organo-metal oxide or organo-metal-containing thin film EUV resist.

In some embodiments of the disclosure, a suitable resist may be an EUV resist that is vapor-deposited on the substrate layer. In other embodiments, a suitable resist may be an EUV resist that is spin-coated on the substrate layer. In some embodiments, the EUV resist may be an organotin oxide. In some embodiments, the dry development process may include a plasma. In other embodiments, the dry development process may be a plasma-free thermal process.

In some embodiments, the dry development process may involve exposure to a compound comprising RxZy, where R=B, Al, Si, C, S, SO with x>0 and Z=Cl, H, Br, F, CH₄ and y>0 at a suitable flow rate for a suitable time, pressure and temperature.

In some embodiments, the photopatterned EUV-resist is an organotin oxide-containing 10-20 nm thick thin film deposited based on a gas phase reaction of the organotin precursor isopropyl(tris)(dimethylamino) tin and water vapor subjected to a EUV exposure dose and post-exposure bake, and the dry development process involves a non-plasma thermal exposure of the photopatterned EUV-resist at 120° C., 10 mT, 500 sccm BCl₃, for 30 seconds.

In some embodiments, the process further involves after dry developing to form the resist mask, etching the substrate layer using the resist mask.

In some embodiments, the resist is sensitive to a radiation source selected from the group consisting of DUV, EUV, X-ray and e-beam radiation.

In other aspects, an apparatus for conducting dry development of a patterned resist is provided. Such an apparatus may include a vacuum process chamber with a substrate (e.g., wafer) support, a vacuum line, a dry development chemistry gas line, one or more heaters for substrate temperature control; and a controller programmed with instructions for processing a semiconductor substrate. The instructions may include code for providing to the vacuum process chamber a patterned resist on a substrate layer on a semiconductor substrate, and removing either an exposed portion or an unexposed portion of the patterned resist by a dry development process comprising exposure to a chemical compound to form a resist mask.

In some embodiments, the process chamber interior of the apparatus may be coated with a corrosion inhibitor.

In some embodiments, the controller may be programmed with instructions for the dry development process wherein the dry development process includes a plasma. In other embodiments, the controller may be programmed with instructions for the dry development process wherein the dry development process is a plasma-free thermal process.

In some embodiments, the controller may be programmed with instructions for the dry development process wherein the dry development process involves exposure to a compound comprising RxZy, where R=B, Al, Si, C, S, SO with x>0 and Z=Cl, H, Br, F, CH₄ and y>0 at a suitable flow rate for a suitable time, pressure and temperature.

In some embodiments, the controller may be programmed with instructions for the dry development process wherein the photopatterned EUV-resist is an organotin oxide-containing 10-20 nm thick thin film deposited based on a gas phase reaction of the organotin precursor isopropyl(tris)(dimethylamino) tin and water vapor subjected to a EUV exposure dose and post-exposure bake, and the dry development process involves a non-plasma thermal exposure of the photopatterned EUV-resist at 120° C., 10 mT, 500 sccm BCl₃, for 30 seconds.

In some embodiments, the controller may be programmed wherein the process further involves after dry developing to form the resist mask, etching the substrate layer using the resist mask.

### BRIEF DESCRIPTION OF THE DRAWINGS

FIGS. 1A-B and 2 illustrate processing stages and result of a negative tone dry development according to a particular embodiment of the present disclosure.

FIG. 3 depicts a schematic illustration of an embodiment of process station apparatus suitable for implementation of described dry development embodiments.

FIG. 4 depicts an embodiment of a multi-station processing tool suitable for implementation of described dry development embodiments.

FIG. 5 schematically shows a cross-sectional view of an inductively coupled plasma apparatus appropriate for implementing certain embodiments or aspects of embodiments.

FIG. 6 depicts a semiconductor process cluster tool architecture with vacuum-integrated deposition and patterning modules that interface with a vacuum transfer module, suitable for implementation of processes described herein.

### DETAILED DESCRIPTION

This disclosure relates generally to the field of semiconductor processing. In particular aspects, the disclosure is directed to process and apparatus for dry development of photoresists (e.g., EUV, DUV, X-ray or e-beam-sensitive metal and/or metal oxide-containing photoresists), for example to form a patterning mask in the context of EUV patterning.

Reference is made herein in detail to specific embodiments of the disclosure. Examples of the specific embodiments are illustrated in the accompanying drawings. While the disclosure will be described in conjunction with these specific embodiments, it will be understood that it is not intended to limit the disclosure to such specific embodiments. On the contrary, it is intended to cover alternatives, modifications, and equivalents as may be included within the spirit and scope of the disclosure. In the following description, numerous specific details are set forth in order to provide a thorough understanding of the present disclosure.

The present disclosure may be practiced without some or all of these specific details. In other instances, well known process operations have not been described in detail so as to not unnecessarily obscure the present disclosure.

Extreme ultraviolet (EUV) lithography can extend lithography technology by moving to smaller imaging source wavelengths than would be achievable with conventional photolithography methods. EUV light sources at approximately 10-20 nm, or 11-14 nm wavelength, for example 13.5 nm wavelength, can be used for leading-edge lithography tools, also referred to as scanners. The EUV radiation is strongly absorbed in a wide range of solid and fluid materials including quartz and water vapor, and so operates in a vacuum. Similar beneficial performance may be obtainable with other forms of radiation, including DUV, X-ray or e-beam radiation. While the description herein primarily references EUV as the resist irradiation source, it should be understood that these other forms of radiation are also contemplated in alternative embodiments.

EUV lithography makes use of EUV resists that are patterned to form masks for use in etching underlying layers. EUV resists may be polymer-based chemically amplified resists (CARs) produced by liquid-based spin-on techniques. An alternative to CARs are directly photopatternable metal oxide-containing films, such as those available from Inpria Corporation, Corvallis, OR, and described, for example, in US Patent Publications US 2017/0102612, US 2016/021660 and US 2016/0116839, incorporated by reference herein at least for their disclosure of photopatternable metal oxide-containing films. Such films may be produced by spin-on techniques or dry vapor-deposited. The metal oxide-containing film can be patterned directly (i.e., without the use of a separate photoresist) by EUV exposure in a vacuum ambient providing sub-30 nm patterning resolution, for example as described in U.S. Pat. No. 9,996,004, issued Jun. 12, 2018 and titled EUV PHOTOPATTERNING OF VAPOR-DEPOSITED METAL OXIDE-CONTAINING HARDMASKS, and/or PCT/US19/31618, filed May 9, 2019 and titled METHODS FOR MAKING EUV PATTERNABLE HARD MASKS, and/or PCT/US2019/060742, filed Nov. 11, 2019 and titled METHODS FOR MAKING HARD MASKS USEFUL IN NEXT-GENERATION LITHOGRAPHY, the disclosures of which at least relating to the composition, deposition and patterning of directly photopatternable metal oxide films to form EUV resist masks is incorporated by reference herein. Generally, the patterning involves exposure of the EUV resist with EUV radiation to form a photo pattern in the resist, followed by development to remove a portion of the resist according to the photo pattern to form the mask.

Directly photopatternable EUV resists may be composed of or contain metals and/or metal oxides mixed within organic components. The metals/metal oxides are highly promising in that they can enhance the EUV photon adsorption and generate secondary electrons and/or show increased etch selectivity to an underlying film stack and device layers. Up to date, these resists have been developed using a wet (solvent) approach, which requires the wafer to move to the track, where it is exposed to developing solvent, dried and baked. This wet development step does not only limit productivity but can also lead to line collapse due to surface tension effects and/or delamination.

In one implementation of the present disclosure, a EUV-sensitive metal oxide-containing film, e.g., an organotin oxide, is vapor-deposited on a semiconductor substrate. The metal oxide-containing film is then patterned directly by EUV exposure in a vacuum ambient, and the pattern is developed to form the metal oxide-containing mask. As described herein, the development of the organo-metal oxide-containing, organo-metal-containing, or other directly photopatternable EUV resist film is conducted by a dry method.

The presently disclosed methods and apparatus provide a general approach that may be applied in various specific implementations. Embodiments of this disclosure provide a process and apparatus configured for dry development of an EUV-photopatterned metal and/or metal oxide-containing resist using a chemical compound as part of a EUV resist mask formation process. Other embodiments include combining all dry steps of film formation by vapor deposition, (EUV) lithographic photopatterning and dry development. Dry development can improve performance (e.g., prevent line collapse due to surface tension and delamination in wet development) and enhance throughput (e.g., by avoiding wet development track). Other advantages may include eliminating the use of organic solvent developers, reduced sensitivity to adhesion issues, and a lack of solubility-based limitations.

According to particular embodiments, a dry method for the development of EUV-sensitive metal and/or metal oxide containing photoresists is provided. One embodiment applies to the dry development of Sn and SnOx (tin oxide)-based resists, containing some amount of C, H and O (and possibly additional components such as F). In various embodiments, the metal oxide-containing film may be a photosensitive metalorganic oxide film, such as an organotin oxide, for example an alkyltin oxide (oxide/hydroxide) RSnOₓOH₍₃₋ₓ₎. Effective compositions include those in which the alkyl substituent is a tert-butyl or iso-propyl substituent in which the carbon atom bonded to the tin atom is bonded to three or two (respectively) other carbon atoms. Such substituents appear to undergo more efficient cleavage on exposure to EUV light resulting in changes allowing pattern development. In various embodiments, the EUV exposure causes loss of the alkyl substituent with formation of a new Sn—O—Sn crosslink, which may occur after the EUV exposure step, for example during a post-exposure bake step during which the film may be exposed to ambient oxygen and/or moisture.

The development can be done by using either a gentle plasma (high pressure, low power) or a thermal process while flowing a dry development chemistry such as BCl₃ or another Lewis Acid, for example. According to a particular embodiment, BCl₃ is able to quickly remove the unexposed material, leaving behind a pattern of the exposed film that can be transferred into the underlying layers by plasma-based etch processes, for example conventional etch processes.

In a dry development process using a gentle plasma or a thermal process (e.g., >5 mT (e.g., >15 mT)/<1000 W (e.g., <500 W) transformer coupled plasma (TCP), (in other embodiments CCP, ICP or downstream plasma may be used), 0 to 300° C. (e.g., 30 to 120° C.), 100 to 1000 sccm (e.g., about 500 sccm) dry development chemistry, for 1 to 3000 seconds (e.g., 10-600 seconds) in accordance with this disclosure, a wafer may directly go to a dry development/etch chamber following photopatterning in an EUV scanner, and skip the material and productivity costs associated with a wet development on the track. Alternatively, a post exposure bake step during which the exposed regions undergo further crosslinking to form a denser SnO₂-like network may be conducted in the development chamber, or another chamber. A dry process can provide more tunability and give further critical dimension (CD) control and scum removal.

By applying a non-plasma thermal approach, productivity can be significantly improved as multiple wafers can be batch developed, at the same time in a low-cost thermal vacuum chamber/oven. A suitable chamber can include a vacuum line, a dry development chemistry gas (e.g., BCl₃) line, and heaters for temperature control. And due to the process being thermal, the chamber interior can be coated with corrosion resistant films, such as organic polymers (such as polytetrafluoroethylene (PTFE), e.g., Teflon™) or inorganic coatings, without risk of removal by plasma exposure.

In various embodiments, the photoresist containing some amount of metal, metal oxide and organic components can be dry developed by a plasma or thermal, plasma (including possibly photoactivated (i.e., lamp-heated, such as UV lamp heated) or a mixture of methods while flowing a dry development gas including a compound of formula RxZy, where R=B, Al, Si, C, S, SO with x>0 and Z=Cl, H, Br, F, CH₄ and y>0.

The dry development can result in a positive or a negative tone, in which the RxZy species selectively removes either the unexposed or the exposed material, leaving behind the exposed or unexposed counterpart as a mask.

The process has been demonstrated for EUV photoresist compositions based on organotin oxides, being applicable to both commercially available spin-coatable formulations, such as are available from Inpria Corporation, and formulations applied using dry vacuum deposition techniques, such as are described in Applicant's prior filings referenced above. Negative tone dry development has been achieved by the selective dry development (removal) of non-EUV exposed regions exposed to flows of BCl₃ without striking a plasma. One specific example of a process for dry development involves an organotin oxide-containing EUV-sensitive resist thin film (e.g., 10-20 nm thick) that is deposited based on a gas phase reaction of the organotin precursor isopropyl(tris)(dimethylamino) tin and water vapor, subjected to a EUV exposure dose and post-exposure bake, and then dry developed using a non-plasma thermal process at 120° C. 10, mT, 500 sccm BCl₃, for 30 seconds.

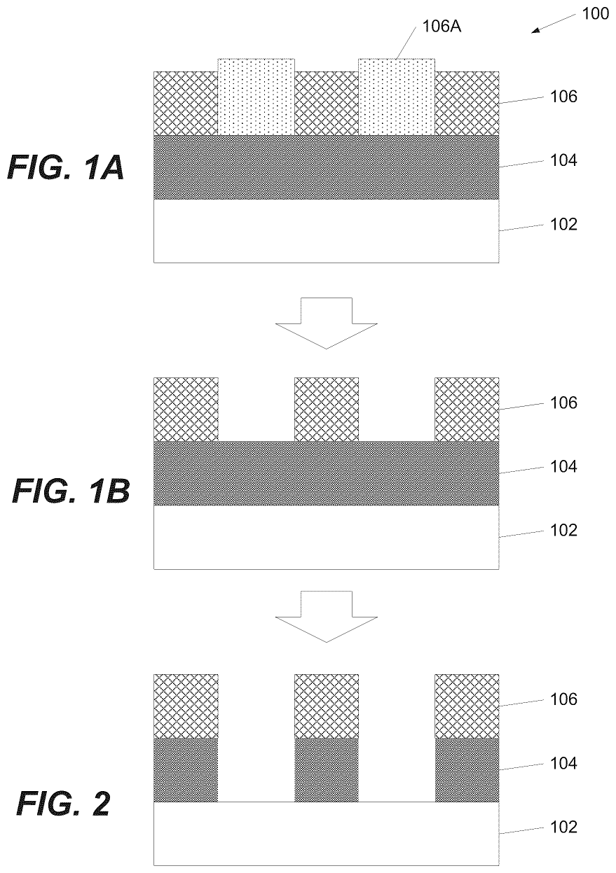

Referring to FIGS. 1A-B and 2, negative tone dry development according to a particular embodiment of the present disclosure is illustrated. As shown in FIG. 1A, a wafer 100, including a substrate 102 (e.g., Si) layer, a layer to be etched 104 (e.g., an ashable hardmask, e.g., siliconoxycarbide (SOC)), or other material, e.g., silicon, silicon oxide, silicon nitride, etc.; in other embodiments may be a layer stack) disposed on the substrate, and a photopatterned EUV resist thin film 106 (e.g., 10-20 nm thick organotin oxide-containing layer disposed on the layer to be etched) can be provided to an etch chamber following photopatterning in an EUV scanner and optional baking as described above. As shown in FIG. 1B, non-EUV exposed regions 106a (darker portions in the figure) of the resist 106 can be removed in a dry development process by exposure to flows of dry development chemistry, such as BCl₃, without striking a plasma. Thereafter, the layer to be etched 104 may be etched using the developed resist 106 as a mask to provide the structure depicted in FIG. 2.

### Alternate Embodiment

Metal and metal oxide-containing EUV-sensitive resists, such as described above, are being adopted in EUV patterning due to their enhanced adsorption of EUV photons. But challenges include high line width and edge roughness, and scumming issues. Both of these challenges can be largely attributed to stochastics and the non-optimal Gaussian distribution of the light resulting in partially or fully exposed material in areas where the resist should remain unexposed or vice versa.

Wet development has very high selectivity and has been shown to exhibit clear on/off behavior, resulting in inability of a wet development process to remove areas that were mistakenly partially or fully exposed. The remaining residues are then left after the wet development process, resulting in scumming and high line edge and width roughness. Interestingly, due to the tunability of the dry development process in which the etch rate and selectivity can be tuned based on multiple knobs, (e.g., time, temperature, pressure, gas/flow) it can be further applied to descum and smooth metal containing resist lines by removing these partially exposed residues.

### Apparatus

As noted above, a suitable process chamber for implementation of a non-plasma thermal embodiment of this disclosure may be composed of a vacuum process chamber with a substrate (e.g., wafer) support, a vacuum line, a BCl₃ line, and one or more heaters for temperature control. The non-plasma thermal process chamber interior can be coated with corrosion resistant organic polymers (such as polytetrafluoroethylene (PTFE), e.g., Teflon™), without risk of removal by plasma exposure.

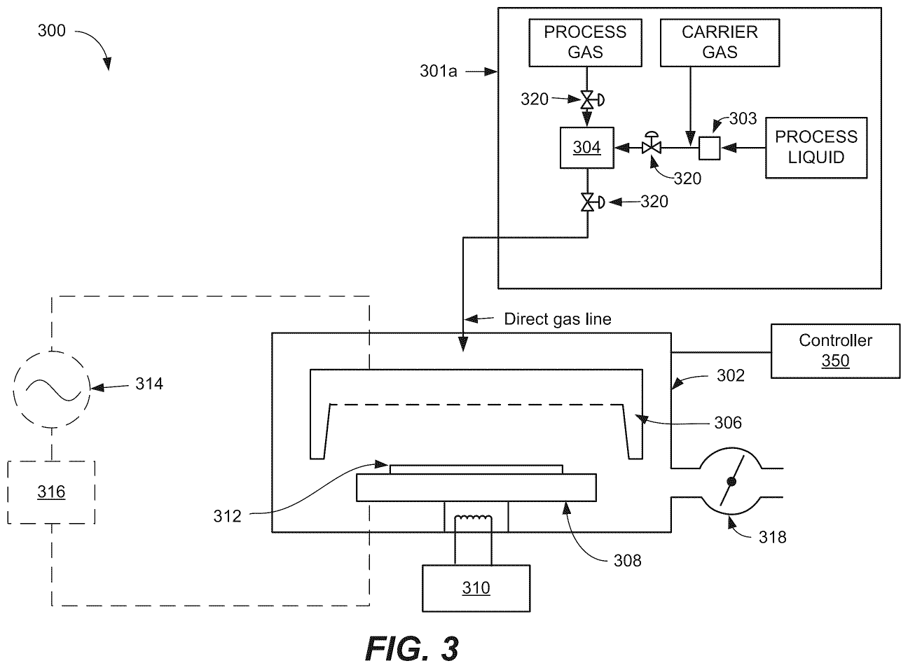

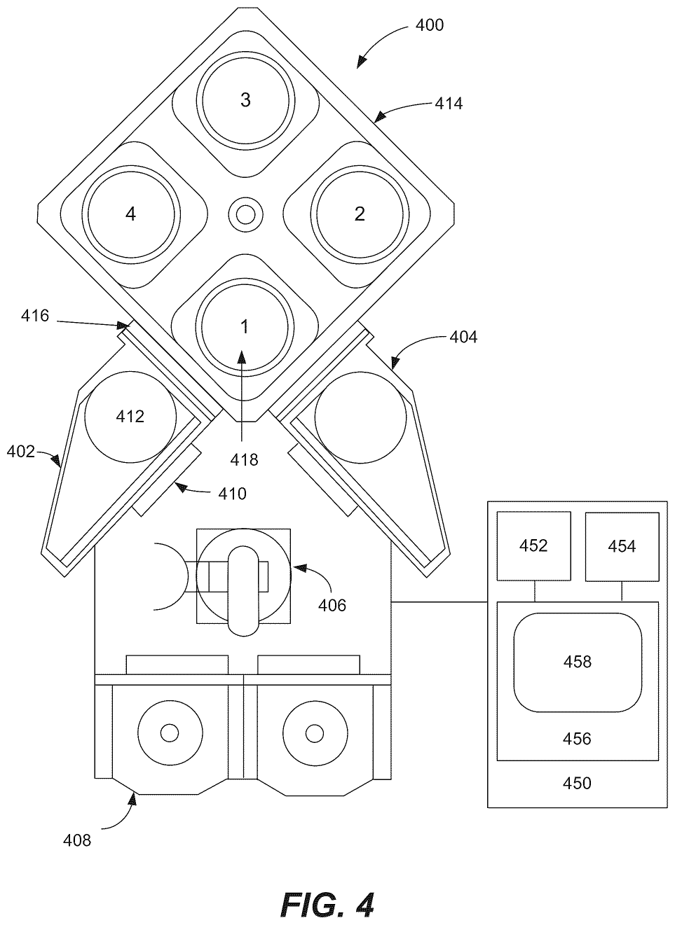

FIG. 3 depicts a schematic illustration of an embodiment of process station 300 having a process chamber body 302 for maintaining a low-pressure environment that is suitable for implementation of described dry development embodiments. A plurality of process stations 300 may be included in a common low pressure process tool environment. For example, FIG. 4 depicts an embodiment of a multi-station processing tool 400, such as a VECTOR® processing tool available from Lam Research Corporation, Fremont, CA. In some embodiments, one or more hardware parameters of the process station 300 including those discussed in detail below may be adjusted programmatically by one or more computer controllers 350.

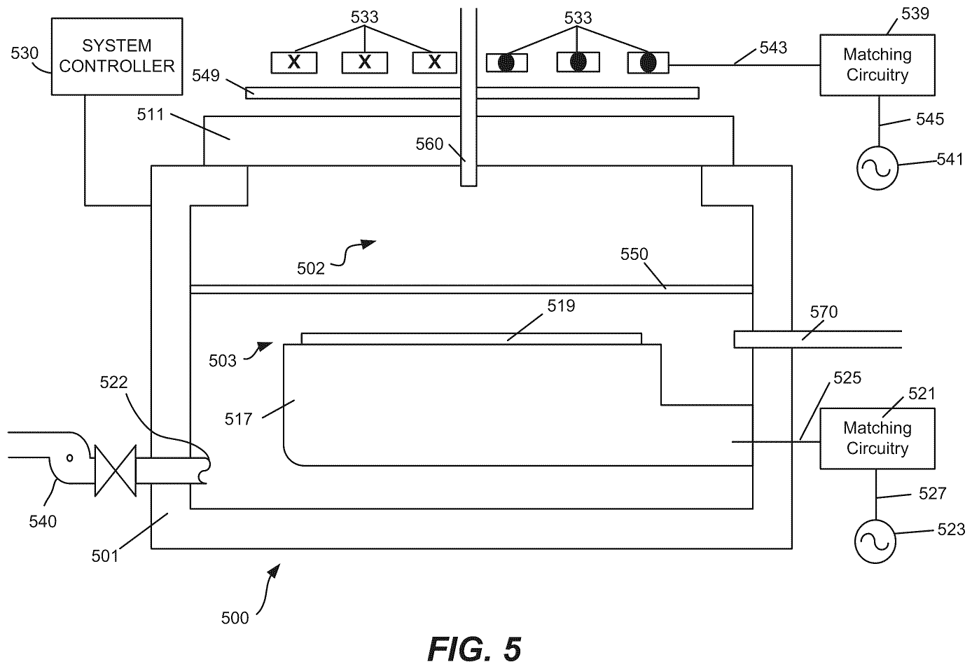

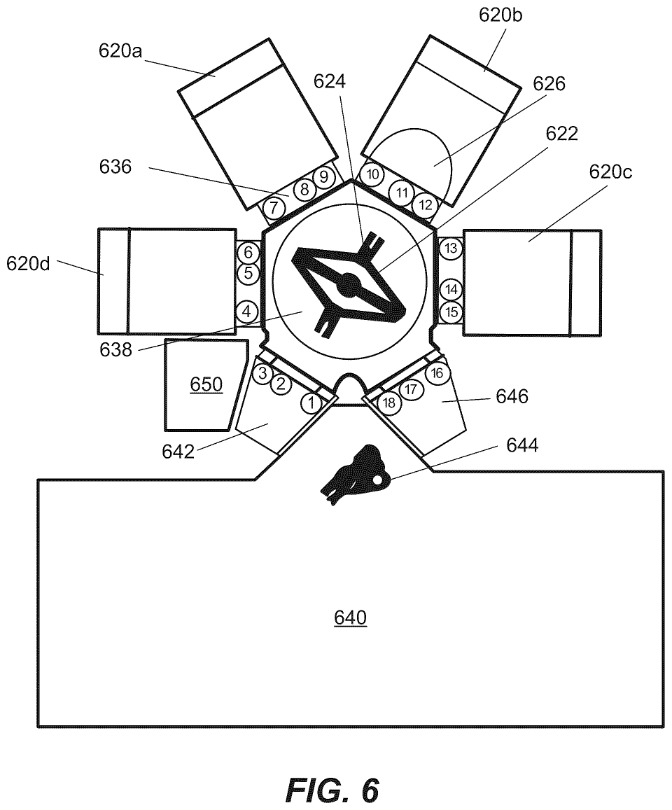

A process station may be configured as a module in a cluster tool. FIG. 6 depicts a semiconductor process cluster tool architecture with vacuum-integrated deposition and patterning modules suitable for implementation of the embodiments described herein. Such a cluster process tool architecture can include resist deposition, resist exposure (EUV scanner), resist dry development and etch modules, as described above and further below with reference to FIGS. 5 and 6.

In some embodiments, certain of the processing functions can be performed consecutively in the same module, for example dry development and etch. And embodiments of this disclosure are directed to methods and apparatus for receiving a wafer, including a photopatterned EUV resist thin film layer disposed on a layer or layer stack to be etched, to a dry development/etch chamber following photopatterning in an EUV scanner; dry developing photopatterned EUV resist thin film layer; and then etching the underlying layer using the patterned EUV resist as a mask, as described herein.

Returning to FIG. 3, process station 300 fluidly communicates with reactant delivery system 301a for delivering process gases to a distribution showerhead 306. Reactant delivery system 301a optionally includes a mixing vessel 304 for blending and/or conditioning process gases, for delivery to showerhead 306. One or more mixing vessel inlet valves 320 may control introduction of process gases to mixing vessel 304. Where plasma exposure is used, plasma may also be delivered to the showerhead 306 or may be generated in the process station 300. As noted above, in at least some embodiments, non-plasma thermal exposure is favored.

FIG. 3 includes an optional vaporization point 303 for vaporizing liquid reactant to be supplied to the mixing vessel 304. In some embodiments, a liquid flow controller (LFC) upstream of vaporization point 303 may be provided for controlling a mass flow of liquid for vaporization and delivery to process station 300. For example, the LFC may include a thermal mass flow meter (MFM) located downstream of the LFC. A plunger valve of the LFC may then be adjusted responsive to feedback control signals provided by a proportional-integral-derivative (PID) controller in electrical communication with the MFM.

Showerhead 306 distributes process gases toward substrate 312. In the embodiment shown in FIG. 3, the substrate 312 is located beneath showerhead 306 and is shown resting on a pedestal 308. Showerhead 306 may have any suitable shape, and may have any suitable number and arrangement of ports for distributing process gases to substrate 312.

In some embodiments, pedestal 308 may be raised or lowered to expose substrate 312 to a volume between the substrate 312 and the showerhead 306. It will be appreciated that, in some embodiments, pedestal height may be adjusted programmatically by a suitable computer controller 350.

In some embodiments, pedestal 308 may be temperature controlled via heater 310. In some embodiments, the pedestal 308 may be heated to a temperature of greater than 0° C. and up to 300° C. or more, for example 50 to 120° C., such as about 65 to 80° C., during non-plasma thermal exposure of a photopatterned resist to dry development chemistry, such as BCl₃, as described in disclosed embodiments.

Further, in some embodiments, pressure control for process station 300 may be provided by a butterfly valve 318. As shown in the embodiment of FIG. 3, butterfly valve 318 throttles a vacuum provided by a downstream vacuum pump (not shown).

However, in some embodiments, pressure control of process station 300 may also be adjusted by varying a flow rate of one or more gases introduced to the process station 300.

In some embodiments, a position of showerhead 306 may be adjusted relative to pedestal 308 to vary a volume between the substrate 312 and the showerhead 306. Further, it will be appreciated that a vertical position of pedestal 308 and/or showerhead 306 may be varied by any suitable mechanism within the scope of the present disclosure. In some embodiments, pedestal 308 may include a rotational axis for rotating an orientation of substrate 312. It will be appreciated that, in some embodiments, one or more of these example adjustments may be performed programmatically by one or more suitable computer controllers 350.

Where plasma may be used, for example in gentle plasma-based dry development embodiments and/or etch operations conducted in the same chamber, showerhead 306 and pedestal 308 electrically communicate with a radio frequency (RF) power supply 314 and matching network 316 for powering a plasma. In some embodiments, the plasma energy may be controlled by controlling one or more of a process station pressure, a gas concentration, an RF source power, an RF source frequency, and a plasma power pulse timing. For example, RF power supply 314 and matching network 316 may be operated at any suitable power to form a plasma having a desired composition of radical species. Examples of suitable powers are up to about 500 W.

In some embodiments, instructions for a controller 350 may be provided via input/output control (IOC) sequencing instructions. In one example, the instructions for setting conditions for a process phase may be included in a corresponding recipe phase of a process recipe. In some cases, process recipe phases may be sequentially arranged, so that all instructions for a process phase are executed concurrently with that process phase. In some embodiments, instructions for setting one or more reactor parameters may be included in a recipe phase. For example, a recipe phase may include instructions for setting a flow rate of a dry development chemistry reactant gas, such as BCl₃, and time delay instructions for the recipe phase. In some embodiments, the controller 350 may include any of the features described below with respect to system controller 450 of FIG. 4.

As described above, one or more process stations may be included in a multi-station processing tool. FIG. 4 shows a schematic view of an embodiment of a multi-station processing tool 400 with an inbound load lock 402 and an outbound load lock 404, either or both of which may include a remote plasma source. A robot 406 at atmospheric pressure is configured to move wafers from a cassette loaded through a pod 408 into inbound load lock 402 via an atmospheric port 410. A wafer is placed by the robot 406 on a pedestal 412 in the inbound load lock 402, the atmospheric port 410 is closed, and the load lock is pumped down. Where the inbound load lock 402 includes a remote plasma source, the wafer may be exposed to a remote plasma treatment to treat the silicon nitride surface in the load lock prior to being introduced into a processing chamber 414. Further, the wafer also may be heated in the inbound load lock 402 as well, for example, to remove moisture and adsorbed gases. Next, a chamber transport port 416 to processing chamber 414 is opened, and another robot (not shown) places the wafer into the reactor on a pedestal of a first station shown in the reactor for processing. While the embodiment depicted in FIG. 4 includes load locks, it will be appreciated that, in some embodiments, direct entry of a wafer into a process station may be provided.

The depicted processing chamber 414 includes four process stations, numbered from 1 to 4 in the embodiment shown in FIG. 4. Each station has a heated pedestal (shown at 418 for station 1), and gas line inlets. It will be appreciated that in some embodiments, each process station may have different or multiple purposes. For example, in some embodiments, a process station may be switchable between dry development and etch process modes. Additionally or alternatively, in some embodiments, processing chamber 414 may include one or more matched pairs of dry development and etch process stations. While the depicted processing chamber 414 includes four stations, it will be understood that a processing chamber according to the present disclosure may have any suitable number of stations. For example, in some embodiments, a processing chamber may have five or more stations, while in other embodiments a processing chamber may have three or fewer stations.

FIG. 4 depicts an embodiment of a wafer handling system 490 for transferring wafers within processing chamber 414. In some embodiments, wafer handling system 490 may transfer wafers between various process stations and/or between a process station and a load lock. It will be appreciated that any suitable wafer handling system may be employed. Non-limiting examples include wafer carousels and wafer handling robots. FIG. 4 also depicts an embodiment of a system controller 450 employed to control process conditions and hardware states of process tool 400. System controller 450 may include one or more memory devices 456, one or more mass storage devices 454, and one or more processors 452. Processor 452 may include a CPU or computer, analog, and/or digital input/output connections, stepper motor controller boards, etc.

In some embodiments, system controller 450 controls all of the activities of process tool 400. System controller 450 executes system control software 458 stored in mass storage device 454, loaded into memory device 456, and executed on processor 452.

Alternatively, the control logic may be hard coded in the controller 450. Applications Specific Integrated Circuits, Programmable Logic Devices (e.g., field-programmable gate arrays, or FPGAs) and the like may be used for these purposes. In the following discussion, wherever “software” or “code” is used, functionally comparable hard coded logic may be used in its place. System control software 458 may include instructions for controlling the timing, mixture of gases, gas flow rates, chamber and/or station pressure, chamber and/or station temperature, wafer temperature, target power levels, RF power levels, substrate pedestal, chuck and/or susceptor position, and other parameters of a particular process performed by process tool 400. System control software 458 may be configured in any suitable way. For example, various process tool component subroutines or control objects may be written to control operation of the process tool components used to carry out various process tool processes. System control software 458 may be coded in any suitable computer readable programming language.

In some embodiments, system control software 458 may include input/output control (IOC) sequencing instructions for controlling the various parameters described above. Other computer software and/or programs stored on mass storage device 454 and/or memory device 456 associated with system controller 450 may be employed in some embodiments. Examples of programs or sections of programs for this purpose include a substrate positioning program, a process gas control program, a pressure control program, a heater control program, and a plasma control program.

A substrate positioning program may include program code for process tool components that are used to load the substrate onto pedestal 418 and to control the spacing between the substrate and other parts of process tool 400.

A process gas control program may include code for controlling gas composition (e.g., BCl₃ gas as described herein) and flow rates and optionally for flowing gas into one or more process stations prior to deposition in order to stabilize the pressure in the process station. A pressure control program may include code for controlling the pressure in the process station by regulating, for example, a throttle valve in the exhaust system of the process station, a gas flow into the process station, etc.

A heater control program may include code for controlling the current to a heating unit that is used to heat the substrate. Alternatively, the heater control program may control delivery of a heat transfer gas (such as helium) to the substrate.

A plasma control program may include code for setting RF power levels applied to the process electrodes in one or more process stations in accordance with the embodiments herein.

A pressure control program may include code for maintaining the pressure in the reaction chamber in accordance with the embodiments herein.

In some embodiments, there may be a user interface associated with system controller 450. The user interface may include a display screen, graphical software displays of the apparatus and/or process conditions, and user input devices such as pointing devices, keyboards, touch screens, microphones, etc.

In some embodiments, parameters adjusted by system controller 450 may relate to process conditions. Non-limiting examples include process gas composition and flow rates, temperature, pressure, plasma conditions (such as RF bias power levels), etc. These parameters may be provided to the user in the form of a recipe, which may be entered utilizing the user interface.

Signals for monitoring the process may be provided by analog and/or digital input connections of system controller 450 from various process tool sensors. The signals for controlling the process may be output on the analog and digital output connections of process tool 400. Non-limiting examples of process tool sensors that may be monitored include mass flow controllers, pressure sensors (such as manometers), thermocouples, etc. Appropriately programmed feedback and control algorithms may be used with data from these sensors to maintain process conditions.

System controller 450 may provide program instructions for implementing the above-described deposition processes. The program instructions may control a variety of process parameters, such as DC power level, RF bias power level, pressure, temperature, etc. The instructions may control the parameters to operate dry development and/or etch processes according to various embodiments described herein.

The system controller 450 will typically include one or more memory devices and one or more processors configured to execute the instructions so that the apparatus will perform a method in accordance with disclosed embodiments. Machine-readable media containing instructions for controlling process operations in accordance with disclosed embodiments may be coupled to the system controller 450.

In some implementations, the system controller 450 is part of a system, which may be part of the above-described examples. Such systems can include semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate.

The electronics may be referred to as the “controller,” which may control various components or subparts of the system or systems. The system controller 450, depending on the processing conditions and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the system controller 450 may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the system controller 450 in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The system controller 450, in some implementations, may be a part of or coupled to a computer that is integrated with, coupled to the system, otherwise networked to the system, or a combination thereof. For example, the system controller 450 may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the system controller 450 receives instructions in the form of data, which specify parameters for each of the processing steps to be performed during one or more operations.

It should be understood that the parameters may be specific to the type of process to be performed and the type of tool that the system controller 450 is configured to interface with or control. Thus as described above, the system controller 450 may be distributed, such as by including one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an ALD chamber or module, an atomic layer etch (ALE) chamber or module, an ion implantation chamber or module, a track chamber or module, an EUV lithography chamber (scanner) or module, a dry development chamber or module, and any other semiconductor processing systems that may be associated or used in the fabrication and/or manufacturing of semiconductor wafers.

As noted above, depending on the process step or steps to be performed by the tool, the system controller 450 might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

Inductively coupled plasma (ICP) reactors which, in certain embodiments, may be suitable for etch operations suitable for implementation of some embodiments, are now described. Although ICP reactors are described herein, in some embodiments, it should be understood that capacitively coupled plasma reactors may also be used.

FIG. 5 schematically shows a cross-sectional view of an inductively coupled plasma apparatus 500 appropriate for implementing certain embodiments or aspects of embodiments such as dry development and/or etch, an example of which is a Kiyo® reactor, produced by Lam Research Corp. of Fremont, CA. The inductively coupled plasma apparatus 500 includes an overall process chamber 524 structurally defined by chamber walls 501 and a window 511. The chamber walls 501 may be fabricated from stainless steel or aluminum. The window 511 may be fabricated from quartz or other dielectric material.

An optional internal plasma grid 550 divides the overall process chamber into an upper sub-chamber 502 and a lower sub chamber 503. In most embodiments, plasma grid 550 may be removed, thereby utilizing a chamber space made of sub chambers 502 and 503. A chuck 517 is positioned within the lower sub-chamber 503 near the bottom inner surface. The chuck 517 is configured to receive and hold a semiconductor wafer 519 upon which the etching and deposition processes are performed. The chuck 517 can be an electrostatic chuck for supporting the wafer 519 when present. In some embodiments, an edge ring (not shown) surrounds chuck 517, and has an upper surface that is approximately planar with a top surface of the wafer 519, when present over chuck 517. The chuck 517 also includes electrostatic electrodes for chucking and dechucking the wafer 519. A filter and DC clamp power supply (not shown) may be provided for this purpose. Other control systems for lifting the wafer 519 off the chuck 517 can also be provided. The chuck 517 can be electrically charged using an RF power supply 523. The RF power supply 523 is connected to matching circuitry 521 through a connection 527. The matching circuitry 521 is connected to the chuck 517 through a connection 525. In this manner, the RF power supply 523 is connected to the chuck 517. In various embodiments, a bias power of the electrostatic chuck may be set at about 50V or may be set at a different bias power depending on the process performed in accordance with disclosed embodiments. For example, the bias power may be between about 20 Vb and about 100 V, or between about 30 V and about 150 V.

Elements for plasma generation include a coil 533 is positioned above window 511. In some embodiments, a coil is not used in disclosed embodiments. The coil 533 is fabricated from an electrically conductive material and includes at least one complete turn. The example of a coil 533 shown in FIG. 5 includes three turns. The cross sections of coil 533 are shown with symbols, and coils having an “X” extend rotationally into the page, while coils having a “⋅” extend rotationally out of the page. Elements for plasma generation also include an RF power supply 541 configured to supply RF power to the coil 533. In general, the RF power supply 541 is connected to matching circuitry 539 through a connection 545. The matching circuitry 539 is connected to the coil 533 through a connection 543. In this manner, the RF power supply 541 is connected to the coil 533. An optional Faraday shield 549a is positioned between the coil 533 and the window 511. The Faraday shield 549a may be maintained in a spaced apart relationship relative to the coil 533. In some embodiments, the Faraday shield 549a is disposed immediately above the window 511. In some embodiments, the Faraday shield 549b is between the window 511 and the chuck 517. In some embodiments, the Faraday shield 549b is not maintained in a spaced apart relationship relative to the coil 533.

For example, the Faraday shield 549b may be directly below the window 511 without a gap. The coil 533, the Faraday shield 549a, and the window 511 are each configured to be substantially parallel to one another. The Faraday shield 549a may prevent metal or other species from depositing on the window 511 of the process chamber 524.

Process gases may be flowed into the process chamber through one or more main gas flow inlets 560 positioned in the upper sub-chamber 502 and/or through one or more side gas flow inlets 570. Likewise, though not explicitly shown, similar gas flow inlets may be used to supply process gases to a capacitively coupled plasma processing chamber. A vacuum pump, e.g., a one or two stage mechanical dry pump and/or turbomolecular pump 540, may be used to draw process gases out of the process chamber 524 and to maintain a pressure within the process chamber 524. For example, the vacuum pump may be used to evacuate the lower sub-chamber 503 during a purge operation of ALD. A valve-controlled conduit may be used to fluidically connect the vacuum pump to the process chamber 524 so as to selectively control application of the vacuum environment provided by the vacuum pump. This may be done employing a closed loop-controlled flow restriction device, such as a throttle valve (not shown) or a pendulum valve (not shown), during operational plasma processing. Likewise, a vacuum pump and valve controlled fluidic connection to the capacitively coupled plasma processing chamber may also be employed.

During operation of the apparatus 500, one or more process gases may be supplied through the gas flow inlets 560 and/or 570. In certain embodiments, process gas may be supplied only through the main gas flow inlet 560, or only through the side gas flow inlet 570. In some cases, the gas flow inlets shown in the figure may be replaced by more complex gas flow inlets, one or more showerheads, for example. The Faraday shield 549a and/or optional grid 550 may include internal channels and holes that allow delivery of process gases to the process chamber 524. Either or both of Faraday shield 549a and optional grid 550 may serve as a showerhead for delivery of process gases. In some embodiments, a liquid vaporization and delivery system may be situated upstream of the process chamber 524, such that once a liquid reactant or precursor is vaporized, the vaporized reactant or precursor is introduced into the process chamber 524 via a gas flow inlet 560 and/or 570.

Radio frequency power is supplied from the RF power supply 541 to the coil 533 to cause an RF current to flow through the coil 533. The RF current flowing through the coil 533 generates an electromagnetic field about the coil 533. The electromagnetic field generates an inductive current within the upper sub-chamber 502.

The physical and chemical interactions of various generated ions and radicals with the wafer 519 etch features of and selectively deposit layers on the wafer 519.

If the plasma grid 550 is used such that there is both an upper sub-chamber 502 and a lower sub-chamber 503, the inductive current acts on the gas present in the upper sub-chamber 502 to generate an electron-ion plasma in the upper sub-chamber 502. The optional internal plasma grid 550 limits the amount of hot electrons in the lower sub-chamber 503. In some embodiments, the apparatus 500 is designed and operated such that the plasma present in the lower sub-chamber 503 is an ion-ion plasma.

Both the upper electron-ion plasma and the lower ion-ion plasma may contain positive and negative ions, though the ion-ion plasma will have a greater ratio of negative ions to positive ions. Volatile etching and/or deposition byproducts may be removed from the lower sub-chamber 503 through port 522. The chuck 517 disclosed herein may operate at elevated temperatures ranging between about 10° C. and about 250° C. The temperature will depend on the process operation and specific recipe.

Apparatus 500 may be coupled to facilities (not shown) when installed in a clean room or a fabrication facility. Facilities include plumbing that provide processing gases, vacuum, temperature control, and environmental particle control. These facilities are coupled to apparatus 500, when installed in the target fabrication facility. Additionally, apparatus 500 may be coupled to a transfer chamber that allows robotics to transfer semiconductor wafers into and out of apparatus 500 using typical automation.

In some embodiments, a system controller 530 (which may include one or more physical or logical controllers) controls some or all of the operations of a process chamber 524. The system controller 530 may include one or more memory devices and one or more processors. In some embodiments, the apparatus 500 includes a switching system for controlling flow rates and durations when disclosed embodiments are performed. In some embodiments, the apparatus 500 may have a switching time of up to about 500 ms, or up to about 750 ms. Switching time may depend on the flow chemistry, recipe chosen, reactor architecture, and other factors.

In some implementations, the system controller 530 is part of a system, which may be part of the above-described examples. Such systems can include semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be integrated into the system controller 530, which may control various components or subparts of the system or systems. The system controller, depending on the processing parameters and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the system controller 530 may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication or removal of one or more layers, materials, metals, oxides, silicon, silicon dioxide, surfaces, circuits, and/or dies of a wafer.

The system controller 530, in some implementations, may be a part of or coupled to a computer that is integrated with, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer.

In some examples, the system controller 530 receives instructions in the form of data, which specify parameters for each of the processing steps to be performed during one or more operations. It should be understood that the parameters may be specific to the type of process to be performed and the type of tool that the controller is configured to interface with or control. Thus as described above, the system controller 530 may be distributed, such as by including one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an ALD chamber or module, an ALE chamber or module, an ion implantation chamber or module, a track chamber or module, an EUV lithography chamber (scanner) or module, a dry development chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

EUVL patterning may be conducted using any suitable tool, often referred to as a scanner, for example the TWINSCAN NXE: 3300B® platform supplied by ASML of Veldhoven, NL). The EUVL patterning tool may be a standalone device from which the substrate is moved into and out of for deposition and etching as described herein. Or, as described below, the EUVL patterning tool may be a module on a larger multi-component tool. FIG. 6 depicts a semiconductor process cluster tool architecture with vacuum-integrated deposition, EUV patterning and dry development/etch modules that interface with a vacuum transfer module, suitable for implementation of the processes described herein.

While the processes may be conducted without such vacuum integrated apparatus, such apparatus may be advantageous in some implementations.

FIG. 6 depicts a semiconductor process cluster tool architecture with vacuum-integrated deposition and patterning modules that interface with a vacuum transfer module, suitable for implementation of processes described herein. The arrangement of transfer modules to “transfer” wafers among multiple storage facilities and processing modules may be referred to as a “cluster tool architecture” system. Deposition and patterning modules are vacuum-integrated, in accordance with the requirements of a particular process. Other modules, such as for etch, may also be included on the cluster.

A vacuum transport module (VTM) 638 interfaces with four processing modules 620a-620d, which may be individually optimized to perform various fabrication processes. By way of example, processing modules 620a-620d may be implemented to perform deposition, evaporation, ELD, dry development, etch, strip, and/or other semiconductor processes. For example, module 620a may be an ALD reactor that may be operated to perform in a non-plasma, thermal atomic layer depositions as described herein, such as Vector tool, available from Lam Research Corporation, Fremont, CA. And module 620b may be a PECVD tool, such as the Lam Vector®. It should be understood that the figure is not necessarily drawn to scale.

Airlocks 642 and 646, also known as a loadlocks or transfer modules, interface with the VTM 638 and a patterning module 640. For example, as noted above, a suitable patterning module may be the TWINSCAN NXE: 3300B® platform supplied by ASML of Veldhoven, NL). This tool architecture allows for work pieces, such as semiconductor substrates or wafers, to be transferred under vacuum so as not to react before exposure. Integration of the deposition modules with the lithography tool is facilitated by the fact that EUVL also requires a greatly reduced pressure given the strong optical absorption of the incident photons by ambient gases such as H₂O, O₂, etc.

As noted above, this integrated architecture is just one possible embodiment of a tool for implementation of the described processes. The processes may also be implemented with a more conventional stand-alone EUVL scanner and a deposition reactor, such as a Lam Vector tool, either stand alone or integrated in a cluster architecture with other tools, such as etch, strip etc. (e.g., Lam Kiyo or Gamma tools), as modules, for example as described with reference to FIG. 6 but without the integrated patterning module.

Airlock 642 may be an “outgoing” loadlock, referring to the transfer of a substrate out from the VTM 638 serving a deposition module 620a to the patterning module 640, and airlock 646 may be an “ingoing” loadlock, referring to the transfer of a substrate from the patterning module 640 back in to the VTM 638. The ingoing loadlock 646 may also provide an interface to the exterior of the tool for access and egress of substrates. Each process module has a facet that interfaces the module to VTM 638. For example, deposition process module 620a has facet 636. Inside each facet, sensors, for example, sensors 1-18 as shown, are used to detect the passing of wafer 626 when moved between respective stations. Patterning module 640 and airlocks 642 and 646 may be similarly equipped with additional facets and sensors, not shown.

Main VTM robot 622 transfers wafer 626 between modules, including airlocks 642 and 646. In one embodiment, robot 622 has one arm, and in another embodiment, robot 622 has two arms, where each arm has an end effector 624 to pick wafers such as wafer 626 for transport. Front-end robot 644, in is used to transfer wafers 626 from outgoing airlock 642 into the patterning module 640, from the patterning module 640 into ingoing airlock 646. Front-end robot 644 may also transport wafers 626 between the ingoing loadlock and the exterior of the tool for access and egress of substrates. Because ingoing airlock module 646 has the ability to match the environment between atmospheric and vacuum, the wafer 626 is able to move between the two pressure environments without being damaged.

It should be noted that a EUVL tool typically operates at a higher vacuum than a deposition tool. If this is the case, it is desirable to increase the vacuum environment of the substrate during the transfer between the deposition to the EUVL tool to allow the substrate to degas prior to entry into the patterning tool. Outgoing airlock 642 may provide this function by holding the transferred wafers at a lower pressure, no higher than the pressure in the patterning module 640, for a period of time and exhausting any off-gassing, so that the optics of the patterning tool 640 are not contaminated by off-gassing from the substrate. A suitable pressure for the outgoing, off-gassing airlock is no more than 1E-8 Torr.

In some embodiments, a system controller 650 (which may include one or more physical or logical controllers) controls some or all of the operations of the cluster tool and/or its separate modules. It should be noted that the controller can be local to the cluster architecture, or can be located external to the cluster architecture in the manufacturing floor, or in a remote location and connected to the cluster architecture via a network. The system controller 650 may include one or more memory devices and one or more processors. The processor may include a central processing unit (CPU) or computer, analog and/or digital input/output connections, stepper motor controller boards, and other like components. Instructions for implementing appropriate control operations are executed on the processor. These instructions may be stored on the memory devices associated with the controller or they may be provided over a network. In certain embodiments, the system controller executes system control software.

The system control software may include instructions for controlling the timing of application and/or magnitude of any aspect of tool or module operation. System control software may be configured in any suitable way. For example, various process tool component subroutines or control objects may be written to control operations of the process tool components necessary to carry out various process tool processes. System control software may be coded in any suitable compute readable programming language. In some embodiments, system control software includes input/output control (IOC) sequencing instructions for controlling the various parameters described above. For example, each phase of a semiconductor fabrication process may include one or more instructions for execution by the system controller. The instructions for setting process conditions for condensation, deposition, evaporation, patterning and/or etching phase may be included in a corresponding recipe phase, for example.

In various embodiments, an apparatus for forming a negative pattern mask is provided. The apparatus may include a processing chamber for patterning, deposition and etch, and a controller including instructions for forming a negative pattern mask. The instructions may include code for, in the processing chamber, patterning a feature in a chemically amplified (CAR) resist on a semiconductor substrate by EUV exposure to expose a surface of the substrate, dry developing the photopatterned resist, and etching the underlying layer or layer stack using the patterned resist as a mask.

It should be noted that the computer controlling the wafer movement can be local to the cluster architecture, or can be located external to the cluster architecture in the manufacturing floor, or in a remote location and connected to the cluster architecture via a network. A controller as described above with respect to any of FIG. 3, 4 or 5 may be implemented with the tool in FIG. 6.

### CONCLUSION

Process and apparatus for dry development of metal and/or metal oxide photoresists, for example to form a patterning mask in the context of EUV patterning is disclosed.

It is understood that the examples and embodiments described herein are for illustrative purposes only and that various modifications or changes in light thereof will be suggested to persons skilled in the art. Although various details have been omitted for clarity's sake, various design alternatives may be implemented. Therefore, the present examples are to be considered as illustrative and not restrictive, and the disclosure is not to be limited to the details given herein, but may be modified within the scope of the disclosure.

1-19. (canceled)

20. A method of processing a semiconductor substrate, comprising:
dry developing a photopatterned resist by removing either an exposed portion or an unexposed portion of the resist by a dry development process comprising exposure to a dry development gas that is selective between an organo-metal-oxide material in the unexposed portion and a metal-oxide material in the exposed portion.

21. The method of claim 20, wherein the unexposed portion of the photopatterned resist is removed.

22. The method of claim 20, wherein the dry development process comprises a gentle plasma.

23. The method of claim 22, wherein the gentle plasma is generated at a pressure of greater than 5 mT and at a plasma power of less than about 1,000 watts.

24. The method of claim 22, wherein the gentle plasma is at a pressure of greater than 15 mT and at a plasma power of less than 500 watts.

25. The method of claim 20, wherein the dry development process comprises a plasma-free thermal process.

26. The method of claim 20, wherein the dry development process comprises a mixture of methods comprising a gentle plasma process and a plasma-free thermal process.

27. The method of claim 20, wherein the photopatterned resist is sensitive to a radiation source selected from the group consisting of DUV, EUV, X-ray, and e-beam radiation.

28. The method of claim 20, wherein the dry development gas comprises RxZy, where R=B, Al, Si, C, S, SO with x>0 and Z=Cl, H, Br, F, CH₄ and y>0.

29. The method of claim 28, wherein the dry development gas comprises BCl₃.

30. The method of claim 28, wherein the dry development gas comprises Lewis Acid.

31. The method of claim 28, wherein the dry development gas comprises BBr₃.

32. The method of claim 28, wherein the dry development gas comprises SOF₂.

33. The method of claim 28, wherein the dry development gas comprises SOCl₂.

34. The method of claim 20, wherein the photopatterned resist is an organotin oxide-containing 10-20 nm thick thin film deposited based on a gas phase reaction of an organotin precursor isopropyl(tris)(dimethylamino) tin and water vapor subjected to a EUV exposure dose and post-exposure bake, and the dry development process comprises a non-plasma thermal exposure of the photopatterned resist at 120° C., 10 mT, 500 sccm BCl₃, for 30 seconds.

35. The method of claim 20, wherein the dry development process is performed at about 0 to 300° C.

36. The method of claim 20, further comprising, after dry developing to form a resist mask, etching a layer below using the resist mask.

37. The method of claim 20, further comprising
exposing a resist on the semiconductor substrate to a radiation source selected from the group consisting of DUV, EUV, X-ray, and e-beam to form the photopatterned resist, and
conducting a bake step to increase crosslinking in the photopatterned resist.

38. The method of claim 37, wherein the dry development and the bake step are performed in the same chamber.

39. The method of claim 37, wherein the dry development is performed in a first chamber, and the bake step is performed in a second chamber that is different from the first chamber.

40. The method of claim 20, further comprising:
tuning the dry development process to descum.

41. An apparatus for conducting dry development of a photopatterned resist, the apparatus comprising:
a process chamber;
a substrate support in the process chamber for holding a substrate with the photopatterned resist;
a gas delivery system fluidly coupled to the process chamber for delivering one or more dry development gases that are selective between an organo-metal-oxide material in an unexposed portion and a metal-oxide material in an exposed portion of the photopatterned resist; and
one or more heaters for substrate temperature control.

42. The apparatus of claim 41, wherein an interior of the process chamber is coated with a corrosion inhibitor.

43. The apparatus of claim 42, wherein the interior of the process chamber is coated with corrosion resistant organic polymers or inorganic coatings.

44. The apparatus of claim 43, wherein the corrosion resistant organic polymers comprise polytetrafluoroethylene.

45. The apparatus of claim 41, further comprising a plasma source.

46. The apparatus of claim 45, wherein the plasma source is configured to generate a transformer coupled plasma, a capacitively coupled plasma, or a downstream plasma.

47. The apparatus of claim 45, further comprising a radio frequency power supply and a matching network configured to power a plasma in the plasma source.

48. The apparatus of claim 47, wherein the plasma source is configured to control a plasma power pulse timing in the plasma.

49. The apparatus of claim 41, wherein the one or more heaters are configured to control a temperature of the substrate to be between about 0° C. and about 300° C.

50. The apparatus of claim 41, wherein the gas delivery system comprises a showerhead and one or more mixing vessels configured to blend or condition the one or more dry development gases, wherein the one or more mixing vessels are fluidly coupled to the showerhead.

51. The apparatus of claim 41, further comprising a vacuum pump configured to remove etching and/or deposition byproducts from the process chamber.

52. The apparatus of claim 41, further comprising a vacuum pump configured to control a process chamber pressure between about 5 mT and about 15 mT.

53. The apparatus of claim 52, wherein the vacuum pump comprises a mechanical dry pump and/or a turbomolecular pump.

54. The apparatus of claim 41, further comprising a controller programmed with instructions to control one or more of the following: a process chamber pressure, a substrate temperature, concentrations of the one or more dry development gases, an RF source power, an RF source frequency, and a plasma power pulse timing.

55. The apparatus of claim 41, wherein the one or more dry development gases comprise BCl₃.

56. The apparatus of claim 41, wherein the gas delivery system is further configured to deliver one or more etch gases to etch a layer below the photopatterned resist.

57. A semiconductor process cluster tool for processing a semiconductor substrate, the semiconductor process cluster tool comprising:
one or more vacuum deposition modules configured to deposit a photoresist on the semiconductor substrate,
a photoresist exposure module configured to expose the photoresist to DUV, EUV, X-ray, or e-beam radiation to form a photopatterned resist,
a resist dry development module, wherein the resist dry development module is configured to expose the photopatterned resist to one or more dry development gases that are selective between an organo-metal-oxide material in an unexposed portion and a metal-oxide material in an exposed portion of the photopatterned resist, and
an etch module configured to etch a layer below the photopatterned resist.

58. The semiconductor process cluster of claim 57,
wherein the one or more vacuum deposition modules comprise an atomic layer deposition (ALD) reactor or a plasma enhanced chemical vapor deposition (PECVD) reactor, and
wherein the photoresist exposure module comprises an EUVL scanner.

59. The semiconductor process cluster of claim 57, further comprising:
a vacuum transport module configured to interface the one or more vacuum deposition modules, the photoresist exposure module, the resist dry development module, and the etch module to transfer the semiconductor substrate among the one or more vacuum deposition modules, the photoresist exposure module, the resist dry development module, and the etch module.
